(19) United States
(12) Patent Application Publication
(10) Pub. No.: US 2025/0234596 A1
(43) Pub. Date: Jul. 17, 2025

(54) DIGITALLY CONFIGURABLE AND OPTICALLY TRANSPARENT RADIO FREQUENCY DEVICE USING CONDUCTIVE OXIDE THIN FILMS

(71) Applicant: BAE Systems Information and Electronic Systems Integration Inc., Nashua, NH (US)

(72) Inventors: Derek Krebs, Churubusco, IN (US); Alexander D. Johnson, Waltham, MA (US); Isaac Wildeson, Nashua, NH (US)

(73) Assignee: BAE Systems Information and Electronic Systems Integration Inc, Nashua, NH (US)

(21) Appl. No.: 18/411,261

(22) Filed: Jan. 12, 2024

(51) Int. Cl. H01L 29/786; H01L 23/528; H01L 27/02; H01L 29/66; H01Q 1/22

(52) U.S. Cl. CPC H10D 30/6755; H01L 23/528; H01Q 1/22; H10D 89/10; H10D 99/00

(57) ABSTRACT

A radio frequency device includes an optically transparent, electrically insulating substrate; a plurality of optically transparent, electrically conductive cells disposed on the substrate; a thin film transistor electrically coupled between an optically transparent electrode of a first one of the cells and an optically transparent electrode of a second one of the cells; and an optically transparent conductive control trace electrically coupled to a control terminal of the transistor. In an example, at least one of the cells is a transparent conductive oxide thin film. Electrodes of the transistor may also be optically transparent.

### FIELD OF DISCLOSURE

The present disclosure relates to radio frequency (RF) devices, and more particularly, to a digitally configurable and optically transparent RF device using conductive oxide thin films.

### BACKGROUND

Radio frequency (RF) devices are capable of conducting, emitting, filtering, and/or absorbing RF energy. For example, antennas are metal conductors used to transmit and receive electromagnetic radiation (EMR) waves, such as radio signals; electronic filters are electrical circuits that attenuate and/or amplify frequency components of an RF signal; and frequency-selective surfaces (FSS) are elements that reflect, transmit, or absorb RF energy. The frequencies and directions of signals that the RF device can transmit, receive, reflect, and filter are a function of the geometry (size and shape) of the device, which can be tailored to suit the needs of a given application. However, non-trivial issues remain with respect to RF device design, particularly with respect to configurability and scalability.

### BRIEF DESCRIPTION OF THE DRAWINGS

FIG. 1 is a schematic diagram of an optically transparent RF device, in accordance with an example of the present disclosure.

FIGS. 2, 3, 4A and 4B are schematic diagrams showing different portions of the optically transparent RF device of FIG. 1, in accordance with an example of the present disclosure.

FIG. 5 is a cross-sectional view of an example optically transparent top gate thin film transistor (TFT) usable in the RF device of FIGS. 1, 2, 3, 4A and 4B, in accordance with an example of the present disclosure.

FIG. 6 is a cross-sectional view of an example optically transparent bottom gate TFT usable in the RF device of FIGS. 1, 2, 3, 4A and 4B, in accordance with another example of the present disclosure.

FIGS. 7A and 7B are schematic diagrams of the optically transparent RF device of FIGS. 1, 2, 3, 4A and 4B configured as a transmission line, in accordance with an example of the present disclosure.

FIG. 8 is a schematic diagram of the optically transparent RF device of FIGS. 1, 2, 3, 4A and 4B configured as a meandered transmission line, in accordance with another example of the present disclosure.

FIGS. 9A and 9B are schematic diagrams of the optically transparent RF device of FIGS. 1, 2, 3, 4A and 4B configured as a tunable or adaptive filter, in accordance with another example of the present disclosure.

FIGS. 10A and 10B are schematic diagrams of the optically transparent RF device of FIGS. 1, 2, 3, 4A and 4B configured as an antenna, in accordance with another example of the present disclosure.

FIG. 11 is a schematic diagram of the optically transparent RF device of FIGS. 1, 2, 3, 4A and 4B configured as a semi-transparent transmit-array antenna, in accordance with another example of the present disclosure.

FIGS. 12A-G are a schematic diagrams of the optically transparent RF device of FIGS. 1, 2, 3, 4A and 4B configured as a semi-transparent cover for an electro-optical (EO) aperture, in accordance with examples of the present disclosure.

FIG. 13 is a flow diagram of a method of fabricating the optically transparent RF device of FIGS. 1-12, in accordance with an example of the present disclosure.

Although the following detailed description refers to illustrative examples, alternatives, modifications, and variations thereof will be apparent in light of this disclosure.

### DETAILED DESCRIPTION

Techniques are described herein for a digitally configurable and optically transparent RF device, which can be adaptively configured to be of any size and active geometry suitable for a given application. In more detail, the RF device includes an optically transparent, electrically insulating substrate. A plurality of optically transparent, electrically conductive cells are disposed on the substrate, for example, in the form of an array. Each of the cells can be configured to provide an element of the RF device, such as an antenna element, a filter element, frequency selective surface, or other passive RF device element. A given cell of the array is coupled to a neighboring cell of the array via an optically transparent thin film transistor (TFT), with an optically transparent conductive control network electrically coupled to the control terminals (gates) of the TFTs. A controller can be used to provide a control signal via the conductive control network to each of the control terminals of respective TFTs within the array, to connect corresponding cells of the array into a functional and optically transparent RF circuit. The circuit may be, for instance, an RF transmission line, an RF antenna, or an RF filter, or a combination of these. In this manner, the configuration (e.g., layout and/or geometry) of the RF device can be adaptively and programmatically controlled, via the controller and transistors, to provide, for example, a digitally configurable and optically transparent transmission line, antenna, filter, or another passive RF device.

In some examples, the cells comprise a transparent conductive oxide thin film, such as indium tin oxide, zinc oxide, indium zinc oxide, indium gallium zinc oxide, fluorine doped zinc oxide, and aluminum doped zinc oxide. The switching devices (TFTs) and conductive control network can also be formed with such oxides. The substrate can also be optically transparent (e.g., sapphire, silicon carbide, plastic, gallium nitride, glass, and/or quartz). In this manner, most or all of the RF device is optically transparent and provides wideband functionality. In use, certain cells of the array can be connected together via the corresponding transistors into a functional RF device having specific geometries, which in turn provide specific RF characteristics, such as resonant frequency and attenuation. The controllable geometries of the RF device can further be used to provide beamforming and multiple polarity types and bandwidths. For example, the RF device can be digitally tuned to specific frequencies and multiple electromagnetic wave polarizations, such as to further increase the security of communications transmissions. In some examples, a width (or height, or both) of at least one of the cells is approximately 1/16 of a wavelength λ of a signal applied to the at least one of the cells. Example applications of the RF device include transparent antennas that can be deployed on a vehicle or aircraft (e.g., windshield-based antenna) or another platform that can use an optically transparent and configurable RF device. Numerous other embodiments and variations will be apparent.

### System Architecture

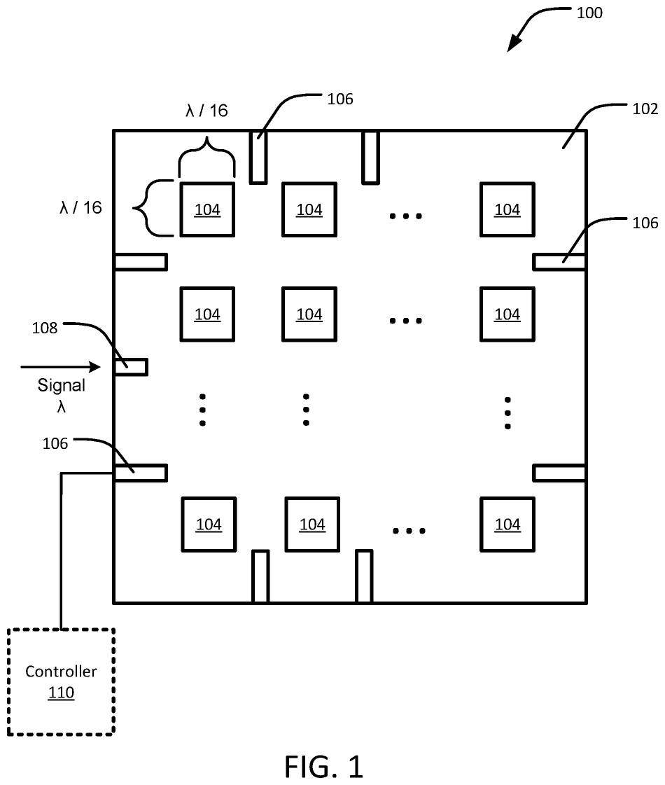

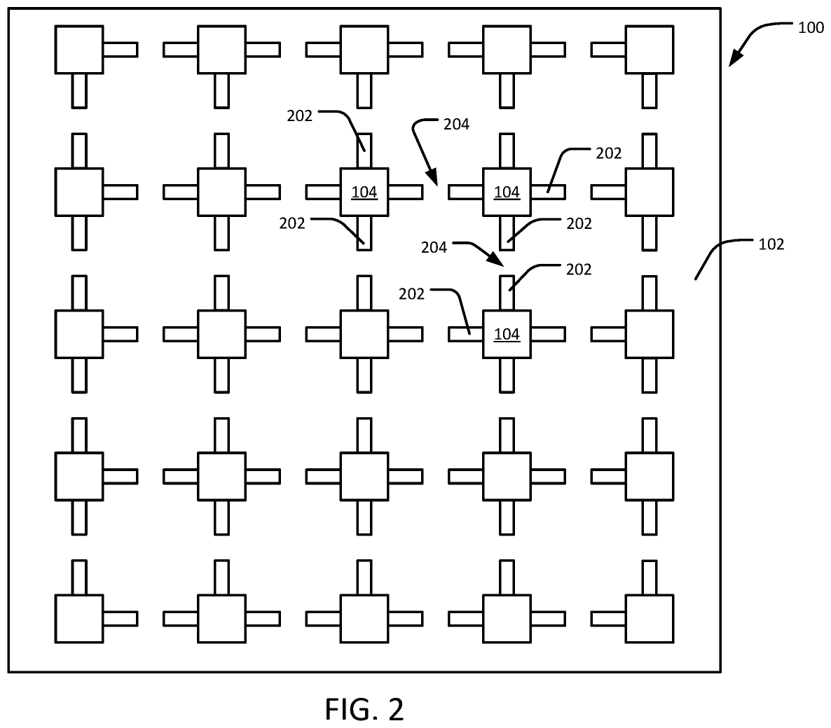

FIG. 1 is a schematic diagram of an optically transparent RF device 100, in accordance with an example of the present disclosure. The device 100 includes an optically transparent, electrically insulating substrate 102 and a plurality of optically transparent, electrically conductive cells 104 disposed on the substrate 102. The device 100 further includes a plurality of electrical contacts 106 along one or more edges of the substrate 102, and an RF input 108. An optically transparent switching and control network (shown in subsequent figures) is electrically coupled to the contacts 106. As further shown, a controller 110 may be communicatively coupled to the contacts 106, and used to configure the RF device. According to some such examples, and as will be described in further detail below, control signals generated by controller 110 are provided to control terminals (e.g., TFT gates) of the switching and control network via the contacts 106, thereby connecting corresponding cells 104 of the array into an antenna structure. As further shown, an RF signal to be transmitted may be received at RF input 108 and applied to the antenna structure formed by the coupled cells 104. The antenna structure can be a receiving antenna that provides a received RF signal at port 108 for subsequent processing (e.g., via an RF frontend receiver circuit). In some examples, control signals generated by controller 110 are provided to connect corresponding cells 104 of the array into a transmission or meander line that is coupled to port 108. In still other examples, control signals generated by controller 110 are provided to connect corresponding cells 104 of the array into an RF filter that is coupled to port 108.

In some examples, each cell is or otherwise includes an optically transparent conductive patch. In some such cases, the height and width of each cell 104 is approximately 1/16 of a wavelength λ of the signal, or greater, to be applied to the device 100. The cells 104 can, for example, be laid out in a column and row grid (two-dimensional array) pattern where each cell 104 is individually controllable via the electrical contacts 106. In this manner, each of the cells 104 can be selectively coupled together to create a geometry that conducts the signal across rows and/or columns of a subset of (or all of) the cells 104 to provide, for example, a tunable filter, a Frequency Selective Surface (FSS), an antenna, an antenna array, or another passive RF device.

The size of the device 100 can be any size and shape suitable for a given application. For example, the substrate 102 can be a flexible material that can conform to the shape of another structure, such as the windshield of a ground vehicle or an airplane, or a housing or body used in other applications where optical transparency of the device 100 is desirable. Further, the size of the device 100, and the number and size of the cells 104, can be scaled to accommodate parameters of a given application, such as the wavelength and the strength of a signal to be emitted from or absorbed by the device 100.

In some examples, the cells 104 comprise, for example, a conducting oxide such as indium tin oxide (ITO), zinc oxide, or other optically transparent conductive material. ITO has an electron energy bandgap of 4 eV, an optical transmittance of greater than 80%, and an electrical resistance of approximately 10⁻⁴ Ω·cm. Such optically transparent and electronically controllable conductive cells can be used for various applications, such as low observables, for same-frequency simultaneous transmit and receive (STaR) filters, switching networks, adaptive arrays, adaptive wideband filtering and signal cancellation architectures to safeguard wideband receivers against both external and self-interference, and other applications for adaptive and flexible control of EMR.

FIGS. 2, 3, 4A and 4B are schematic diagrams showing different portions of the optically transparent RF device 100 of FIG. 1, in accordance with an example of the present disclosure. FIG. 2 shows the substrate 102 and the cells 104 arranged in a grid pattern of five-by-five, although other arrangements of the cells 104 are possible (e.g., larger or smaller grids, or other geometric shaped layout patterns such as rectangles or circles). The substrate 102 can include an optically transparent insulating or semi-insulating material, such as glass, sapphire, silicon carbide, plastic, semiconductor, or an insulated metal. Some semiconductor examples for substrate 102 include, for instance, a gallium nitride (GaN) substrate, or GaN on diamond, both of which are optically transparent, with the diamond providing thermal management. As discussed with reference to FIG. 1, the cells 104 can include an optically transparent conducting (or semiconducting) oxide, such as indium tin oxide, zinc oxide, indium zinc oxide, indium gallium zinc oxide, fluorine doped zinc oxide, and aluminum doped zinc oxide. In some examples, the RF device 100 is approximately 9 cm wide by 9 cm high and includes an 11-by-11 array, although it will be understood that the dimensions of the RF device 100 can be adapted for a given application.

In this example, the cells 104 are square or rectangular and have four adjacent source or drain electrodes 202, one on each side of the cell 104. Cells 104 along the edges of the grid can have two or three such adjacent electrodes 202, depending on the relative locations of the cells 104 to each other, such as shown in FIG. 2. The electrodes 202 can include the same optically transparent conductive oxide as the cells 104. The electrodes 202 of adjacent cells 104 are separated by a gap 204. In an example, the width of each gap 204 is less than approximately 1/16 of a wavelength λ of the signal to be applied to the device 100. The cells 104 and electrodes 202 can be deposited and patterned on the substrate 102 using techniques such as sputtering, lithography, and/or etching of a layer of conducting material deposited onto substrate 102.

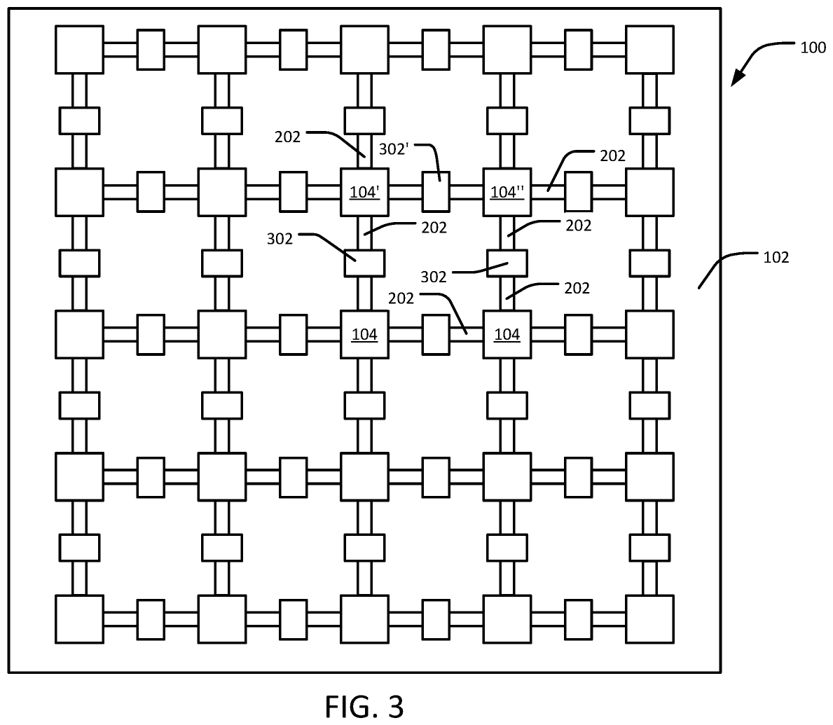

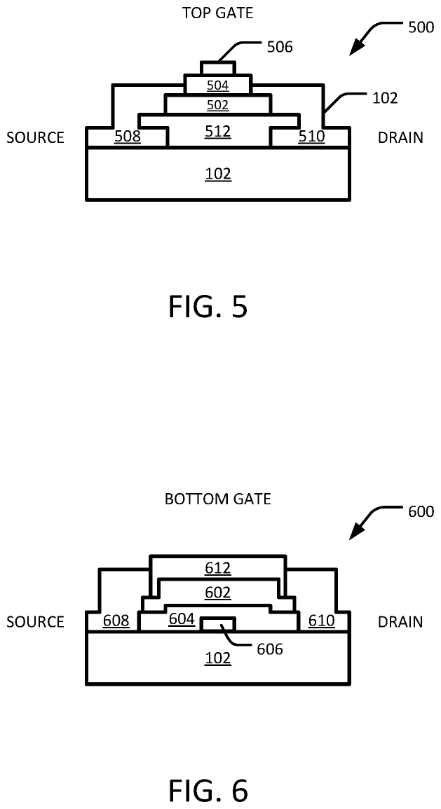

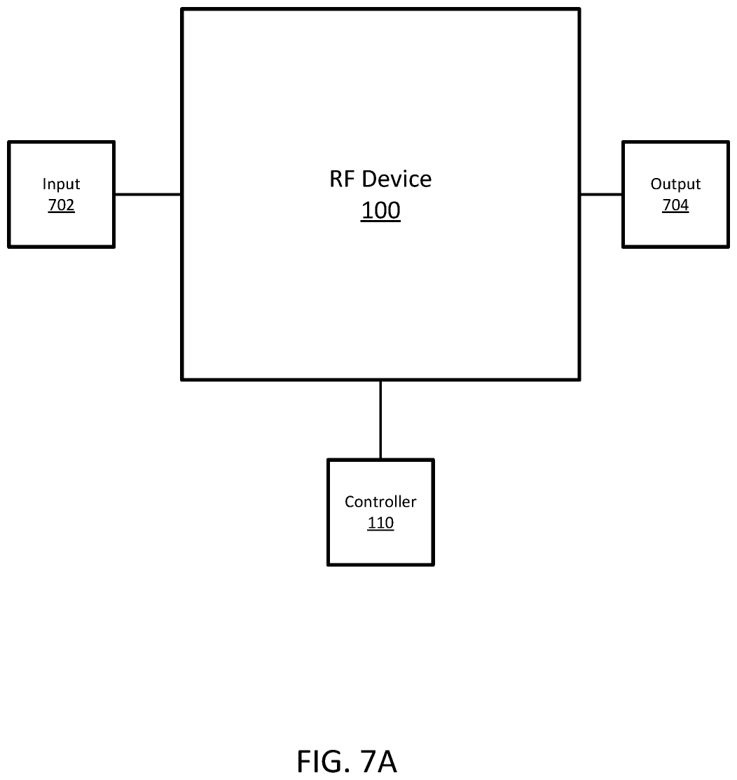

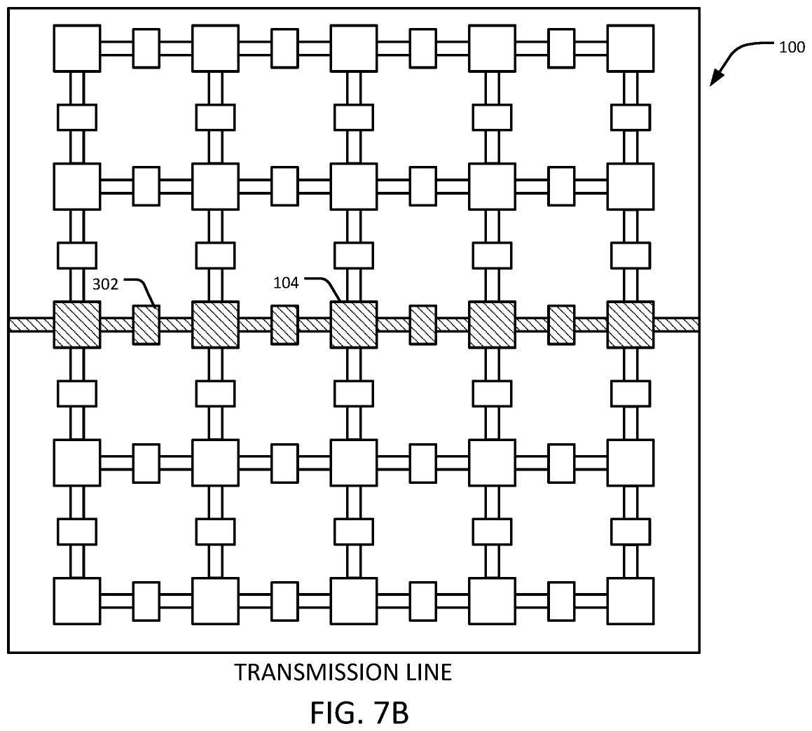

FIG. 3 shows the RF device 100 of FIGS. 1 and 2 with a remainder of a thin film transistor 302 formed over the gap 204, between an electrode of a first cell 104′ and an electrode of a second cell 104″. Additional transistors 302 are formed over the gaps 204 between other electrodes of the cells 104, such as further shown in FIG. 3. Each transistor 302 has a semiconductor or channel region that is coupled between corresponding source and drain electrodes of neighboring cells. For example, the channel region of the transistor 302 is electrically coupled between the source electrode 202 of the first cell 104′ and the drain electrode 202 of the second cell 104″, or vice versa. Each transistor 302 further includes a gate structure on the channel region and between the source and drain electrodes, with the gate structure including a gate dielectric and gate electrode. Like the source and drain electrodes 202, the gate electrode and channel region can be optically transparent material. Further example details of transistors 302 are described with reference to FIGS. 5 and 6. Each thin film transistor 302 acts as an RF switch between adjacent cells 104. In combination, several of the thin film transistors 302 can be switched to form an RF structure (e.g., antenna or filter) or signal path through some or all of the cells 104, such as further described with respect to FIGS. 7A, 7B, 8, 9A, 9B, 10A, 10B, 11 and 12.

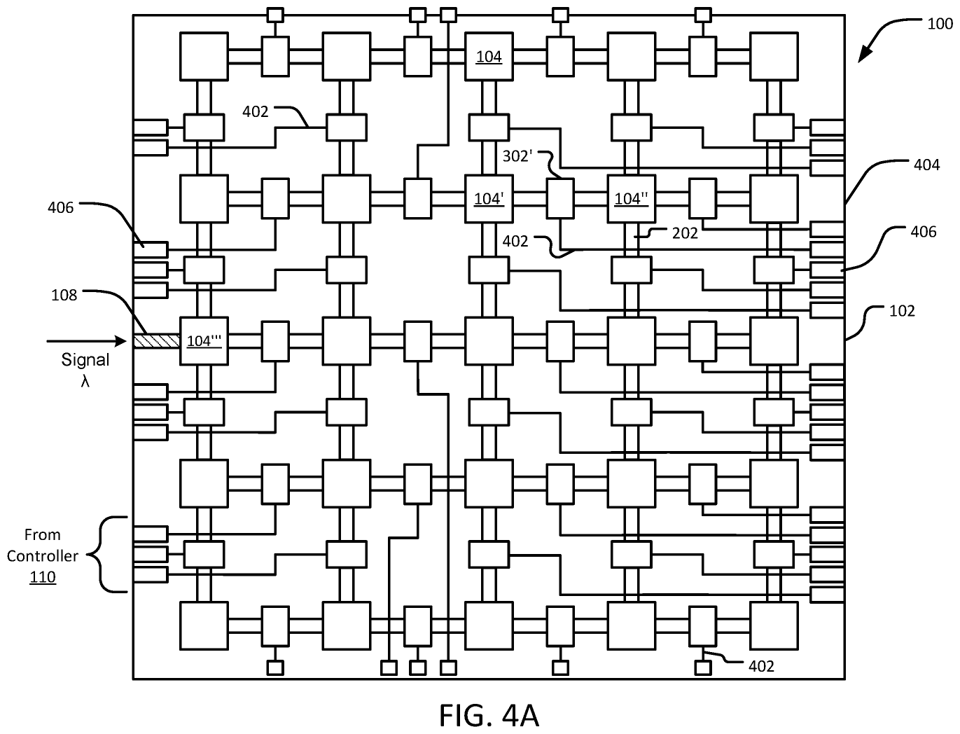

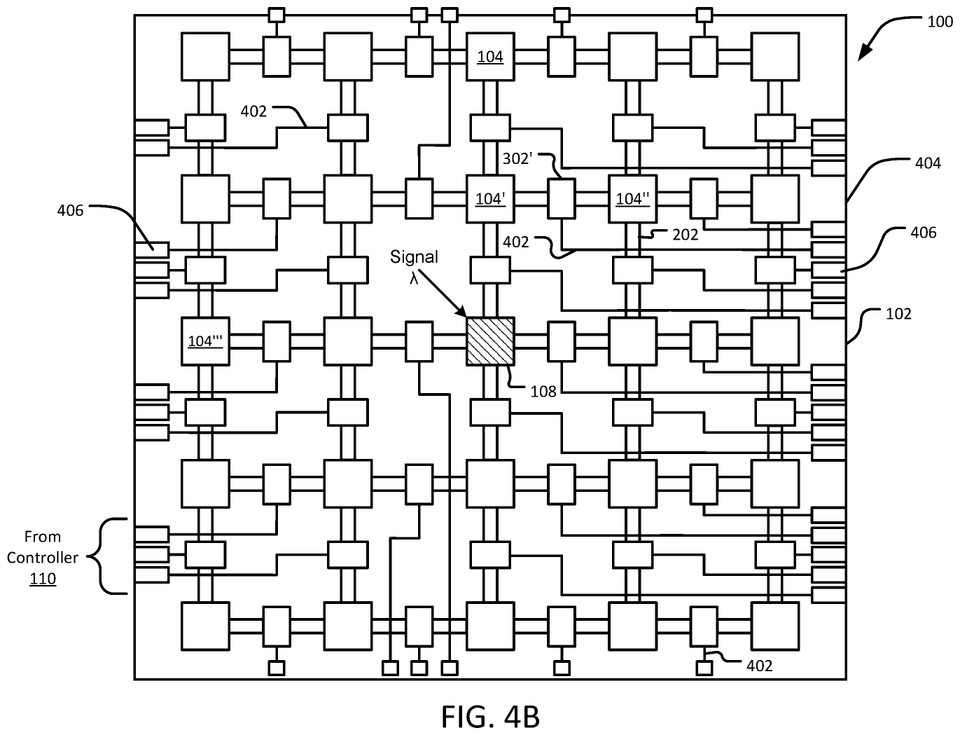

FIGS. 4A and 4B show the optically transparent RF device 100 of FIGS. 1-3 with a plurality of conductive control traces 402 each electrically coupled to the gate electrode of one of the transistors 302. Each of the conductive control traces 402 extends from the gate electrode of the respective transistor 302 to an edge 404 of the substrate 102. The pitch (spacing) of the transistors 302 and the cells 104 can be set to provide sufficient spacing on the substrate 102 between the transistors 302 and the cells 104 for fanout of the control traces 402 to the edge 404 of the substrate 102. A dielectric layer can be used to electrically isolate conductive control traces 402 from the source/drain electrodes 202 of the cells 104 where they overlap or otherwise cross each other. To minimize the number of isolating dielectric layers, the fanout of the control traces 402 can be arranged such that no more than, for example, two conductive control traces 402 overlap at any given point. The conductive control traces 402 can include the same optically transparent conductive oxide as the cells 104. In some examples, the conductive control traces 402 include an optically non-transparent metal with trace line widths thin enough (e.g., <100 μm width) that they do not significantly hinder the overall transparency of the RF device. As further shown in this example, the conductive control traces 402 terminate at edge contacts 406, which allow for coupling the controller 110, which may be configured to drive a control voltage for switching the respective transistor 302 between on and off states.

In operation, for example, when the transistor 302′ is selected with a gate voltage applied to the gate electrode, the signal from the RF input 108 can be coupled into the RF device so that it eventually flows through the transistor 302′ between cell 104′ and cell 104″. Likewise, when the transistor 302′ is not selected (no gate voltage is applied to the gate electrode, or an off-state voltage), no signal flows through the transistor 302′ and the first cell 104′ and the second cell 104″ are electrically isolated at least through the transistor 302′. In other words, the transistors 302 are individually controllable electrical pathways between adjacent cells 104. It will be understood, however, that the first cell 104′ and the second cell 104″ can be in electrical communication with each other via one or more paths through other transistors 302 in the device 100.

In some examples, the RF input 108 is coupled to one of the cells 104″ via a conductor extending from the edge 404 of the substrate 102 to the cell 104″, such as shown in FIG. 4A. In some other examples, the RF input 108 is coupled to the cells 104 from a central portion of the device 100, such as shown in FIG. 4B. In any event, the RF input 108 can be coupled to any one of the cells 104 either directly or via one of the transistors 302.

### Example Thin Film Transistor Structures

FIG. 5 is a cross-sectional view of a thin film transistor 500, in accordance with an example of the present disclosure. The thin film transistor 302 of any of FIGS. 3, 4A and 4B, including the corresponding source and drain electrodes 202 of the neighboring cells, can be used to form the thin film transistor 500. The thin film transistor 500 includes a transparent conducting oxide channel 502, a gate dielectric 504, a gate electrode 506, a source electrode 508, a drain electrode 510, and a dielectric 512. The source electrode 508 and the drain electrode 510, which at least partially correspond to respective electrodes 202, can include a transparent conducting oxide and are coupled to the channel 502. In this example, the thin film transistor 500 has a top gate structure, where the gate electrode 506 is above the channel 502, and the thin film transistor 500 is located on the substrate 102. Note that the gap 204 described with reference to FIG. 2 corresponds to the gap between electrodes 508 and 510, which is filled with dielectric material 512 in this example.

In an example, the thin film transistor 500 can be fabricated by depositing a layer of the dielectric 512 on the substrate 102 (in which substrate 102 is already patterned with the optically transparent cells 104 and electrodes 202; note that electrodes 202 may correspond to the lower horizontal portions of electrodes 508 and 510 depicted in FIG. 5), followed by a layer of semiconductor material for the channel 502, followed by a layer of the gate dielectric 504 and gate electrode 506. Next, portions of the gate dielectric 504 and the channel 502 on either side of the gate electrode 506 can be removed by etching and replaced with additional electrode material for source electrode 508 and the drain electrode 510. In some such examples, the semiconductor material for the channel 502 may be, for example, indium gallium zinc oxide (IGZO) or other suitable channel material that is optically transparent. The dielectric 504 may be any suitable gate dielectric, such as silicon dioxide. The dielectric 512 may be the same as dielectric 504, but may also be a different dielectric. Gate electrode 506 can be, for instance, the same optically transparent material as used for electrodes 204, 508, and 510. Standard lithographic and deposition techniques can be used.

FIG. 6 is a cross-sectional view of a thin film transistor 600, in accordance with another example of the present disclosure. The thin film transistor 302 of any of FIGS. 3, 4A and 4B can include the thin film transistor 600. The thin film transistor 600 includes an optically transparent conducting oxide channel 602, a gate dielectric 604, a gate electrode 606, a source electrode 608, a drain electrode 610, and a dielectric 612. The source electrode 608 and the drain electrode 610, which at least partially correspond to respective electrodes 202, can include a transparent conducting oxide and are coupled to the channel 602, to either side of the gate structure. In this example, the thin film transistor 600 has a bottom gate structure, where the gate electrode 606 is below the channel 602, and the thin film transistor 600 is located on the substrate 102. Note that the gap 204 described with reference to FIG. 2 corresponds to the gap between electrodes 608 and 610, which in this example is filled with the gate structure, with the gate dielectric 604 electrically isolating the gate electrode 606 from electrodes 608 and 610.

In an example, the thin film transistor 600 can be fabricated by depositing the gate electrode 606 on the substrate 102, followed by a layer of the gate dielectric 604, followed by a layer of semiconducting oxide material (e.g., IGZO) for the channel 602, followed by a layer of the dielectric 612, which may be the same material as the gate dielectric 604. Next, portions of the dielectric 612 and the channel 602 on either side of the gate electrode 606 can be removed by etching and replaced with more optically transparent electrode material for the source electrode 608 and the drain electrode 610. Standard lithographic and deposition techniques can be used.

### Example Geometries

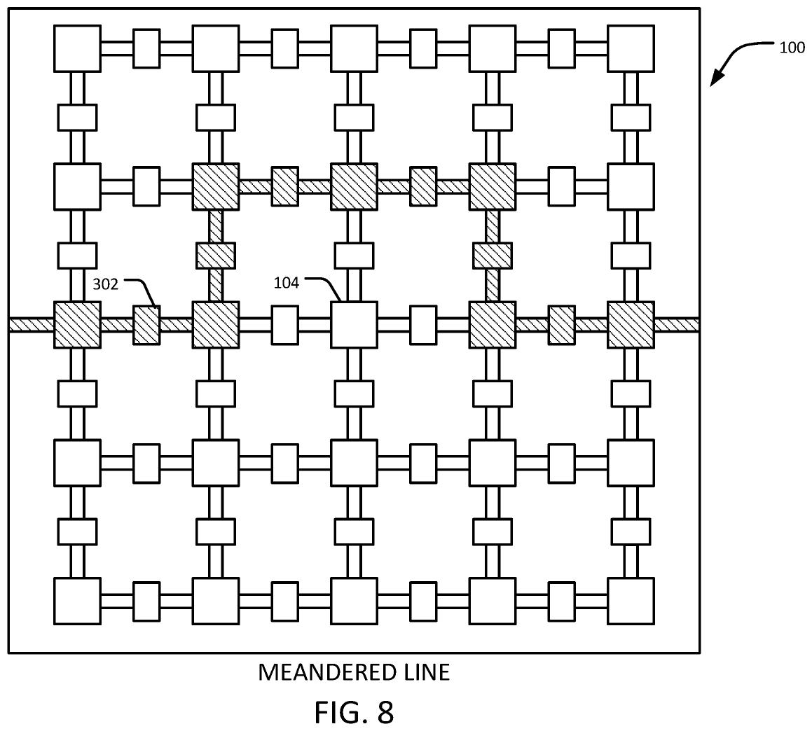

FIGS. 7A and B are schematic diagrams of the optically transparent RF device 100 of FIGS. 1, 2, 3, 4A and 4B configured as a transmission line, in accordance with an example of the present disclosure. In this example, the RF device 100 is coupled to an input 702 (e.g., an RF input) and an output 704 (e.g., an RF output). The controller 110 applies a voltage to a subset of the transistors 302 between a subset of the cells 104 along a line extending from one side of the device 100 to an opposite side, as indicated by the highlighted elements in FIG. 7B. In this manner, an RF signal can traverse the device 100 along the transmission line. The controller 110 can change the configuration of the transmission line by changing the selection of transistors 302 to activate different patterns of the cells 104, such as shown in FIG. 8.

FIG. 8 is a schematic diagram of the optically transparent RF device 100 of FIGS. 1, 2, 3, 4A and 4B configured as a meandered transmission line, in accordance with another example of the present disclosure. In this example, the controller 110 applies a voltage to a subset of the transistors 302 between a subset of the cells 104 along a meandered line extending from one side of the device 100 to an opposite side, as indicated by the highlighted elements in FIG. 8. In this manner, an RF input signal can traverse the RF device 100 along the meandered transmission line. The configuration of the meandered transmission line, and thus the length of the signal path, can be changed by changing the selection of transistors 302 to activate different patterns of the cells 104.

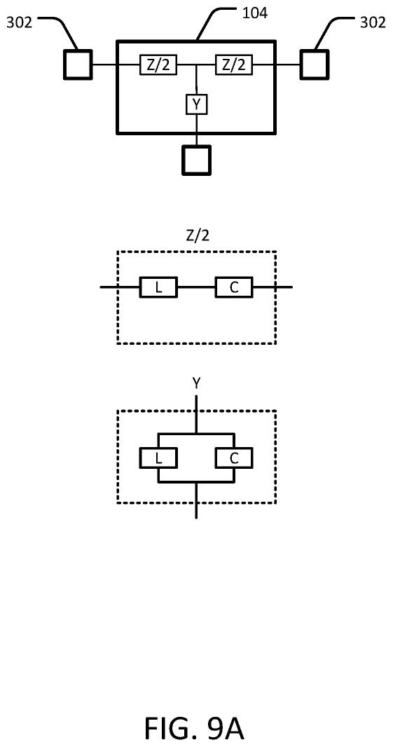

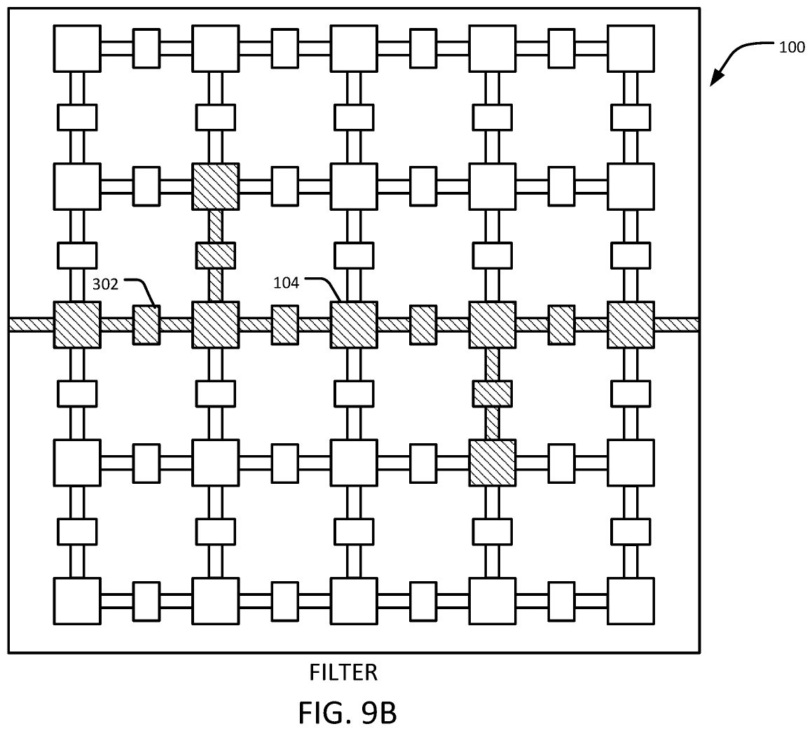

FIGS. 9A and B are schematic diagrams of the optically transparent RF device 100 of FIGS. 1, 2, 3, 4A and 4B configured as a tunable or adaptive filter, in accordance with another example of the present disclosure. In this example, at least one of the cells 104 is configured as a filter. For example, the cell 104 can include inductive elements Z/2 and a filter element Y, where the inductive elements Z/2 include an inductor and capacitor in series and the filter element Y includes an inductor and capacitor in parallel to provide a current load through the cell 104. The controller 110, such as shown in FIGS. 1 and 7A, applies a voltage to a subset of the transistors 302 between a subset of the cells 104 extending from one side of the device 100 to an opposite side, as indicated by the highlighted elements in FIG. 9B. In this manner, an RF signal can traverse the device 100 along the selected cells 104 and be filtered accordingly. The configuration of the filter can be changed by changing the selection of transistors 302 to activate different patterns of the cells 104.

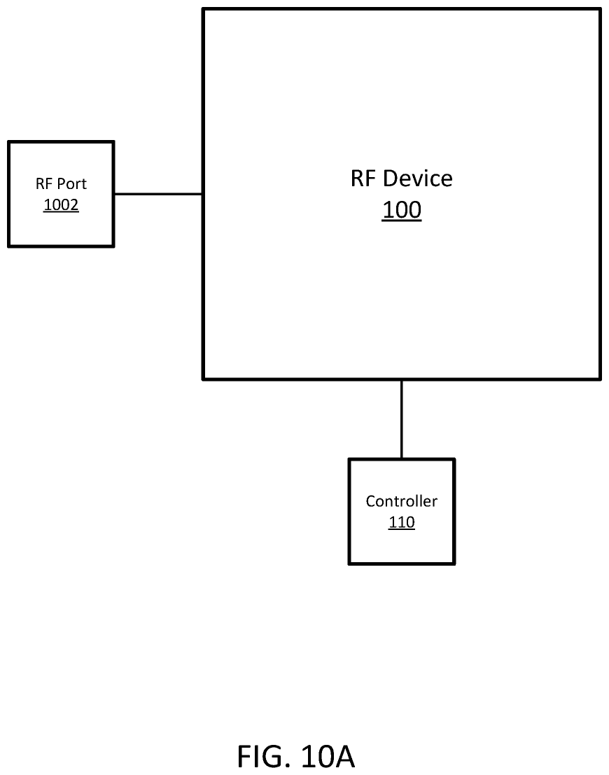

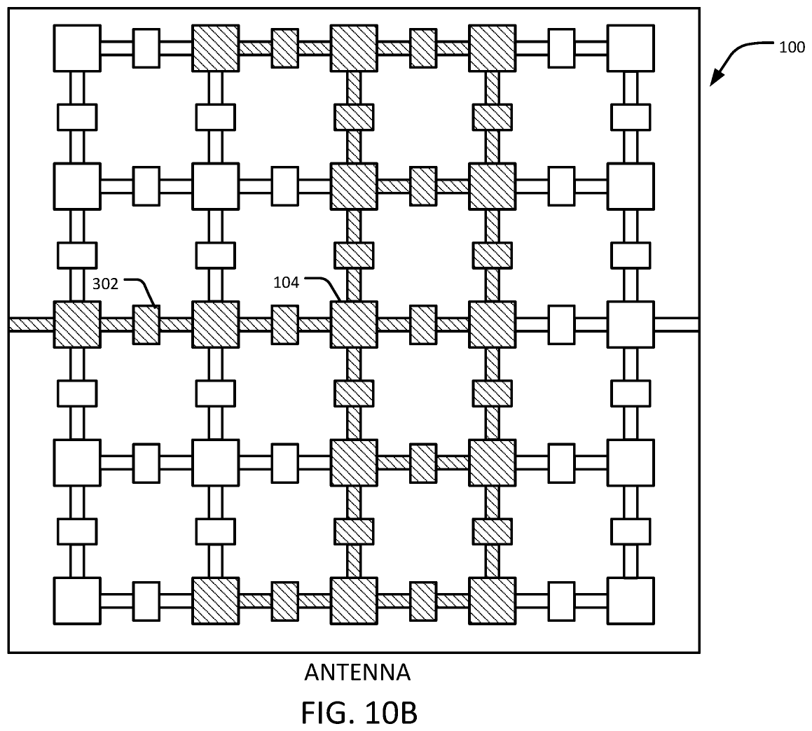

FIGS. 10A and B are schematic diagrams of the optically transparent RF device 100 of FIGS. 1, 2, 3, 4A and 4B configured as an antenna, in accordance with another example of the present disclosure. In this example, the RF device 100 is coupled to an RF port 1002. The controller 110 applies a voltage to a subset of the transistors 302 between a subset of the cells 104, as indicated by the highlighted elements in FIG. 10B, to form an antenna pattern, such as a fractal antenna pattern, a phased antenna array, or another array of interconnected antennas. In this manner, an RF signal can radiate from (transmit) or to (receive) the device 100 along the selected cells 104 and act as an antenna. The configuration of the antenna can be changed by changing the selection of transistors 302 to activate different patterns of the cells 104. In this manner, the device 100 can be digitally tuned to specific frequencies and/or to multiple electromagnetic wave polarizations.

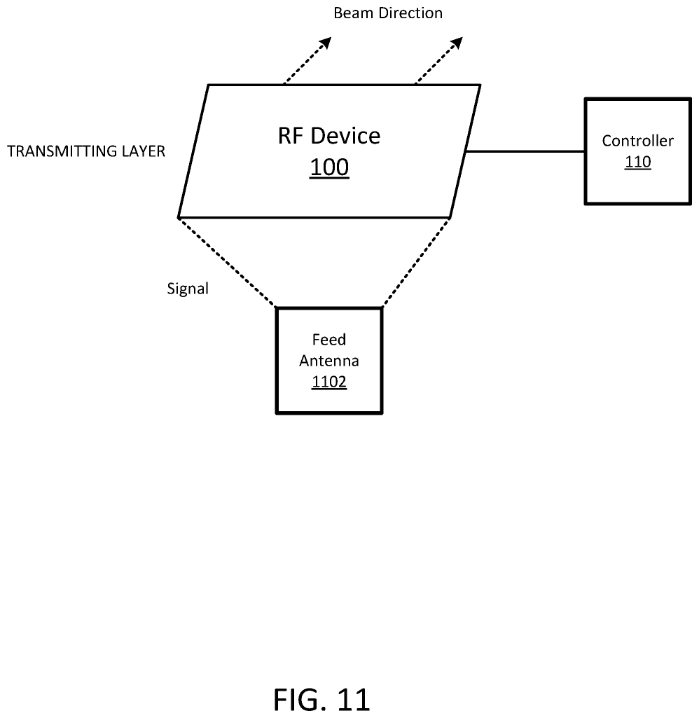

FIG. 11 is a schematic diagram of the optically transparent RF device 100 of FIGS. 1, 2, 3, 4A and 4B configured as a transmit-array antenna, in accordance with another example of the present disclosure. In this example, the RF device 100 is positioned above a feed antenna 1102 such that the signal emitted from the feed antenna 1102 passes through the transmit-array. In some examples, a transparent structure (e.g., glass, plastic, etc.) can be used to mount or otherwise position the RF device 100 above the feed antenna 1102. The controller 110 applies a voltage to a subset of the transistors 302 between a subset of the cells 104 to provide a reconfigurable transmitting layer, where the focusing (beam) direction is a function of the signal in each selected cell 104. In this manner, a signal can radiate through the selected cells 104 and act as a transmit-array. The configuration of the antenna can be changed by changing the selection of transistors 302 to activate different patterns of the cells 104. In this manner, the device 100 can be digitally tuned to specific frequencies and/or to multiple electromagnetic wave polarizations.

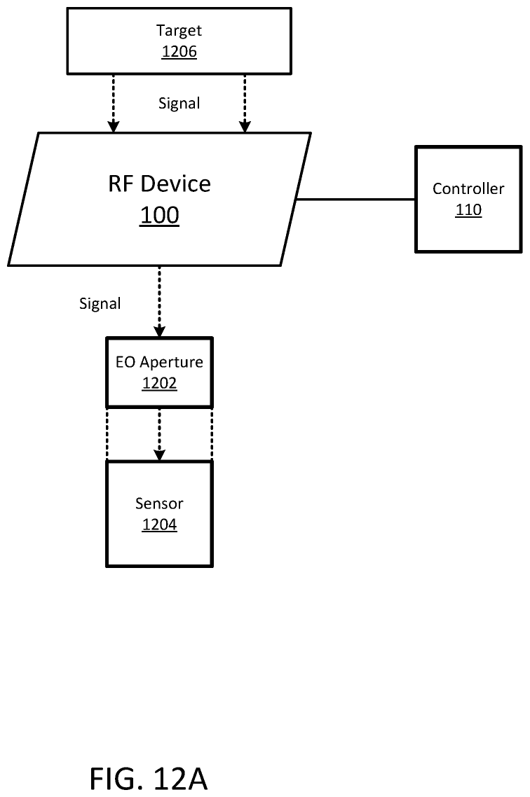

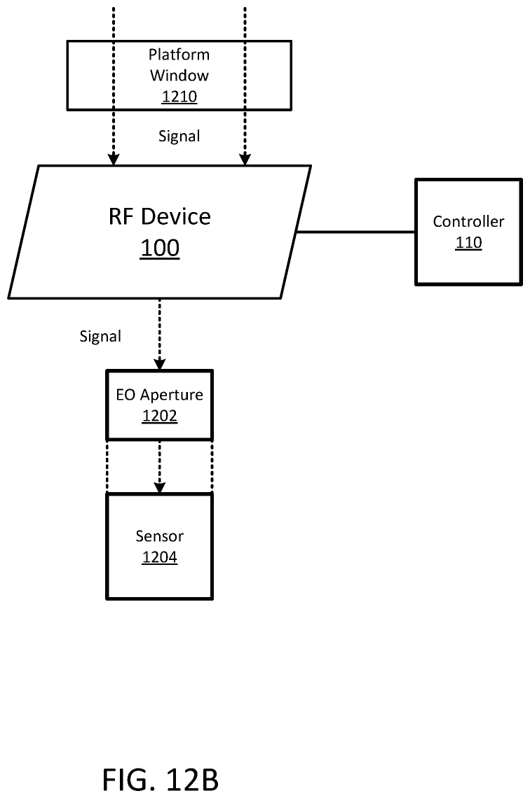

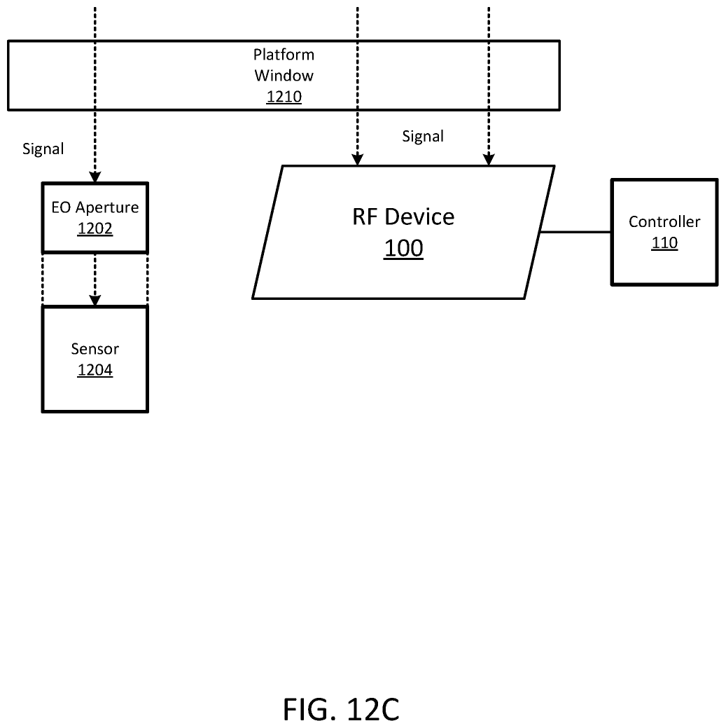

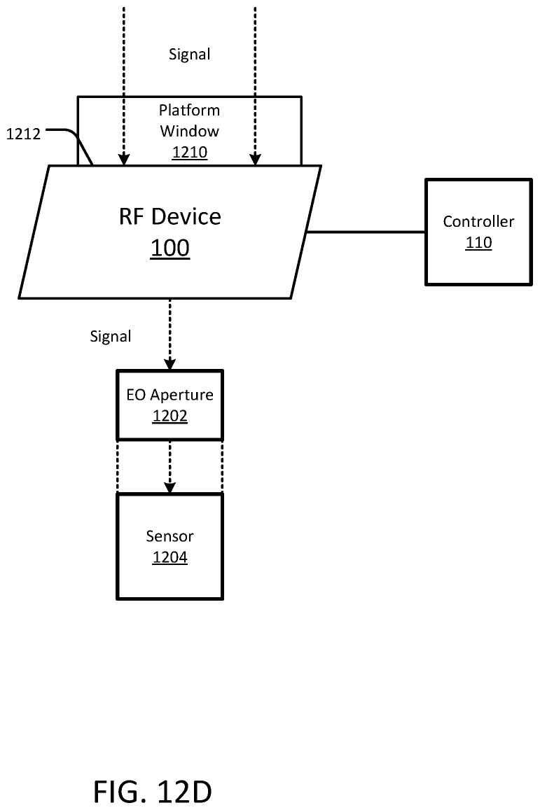

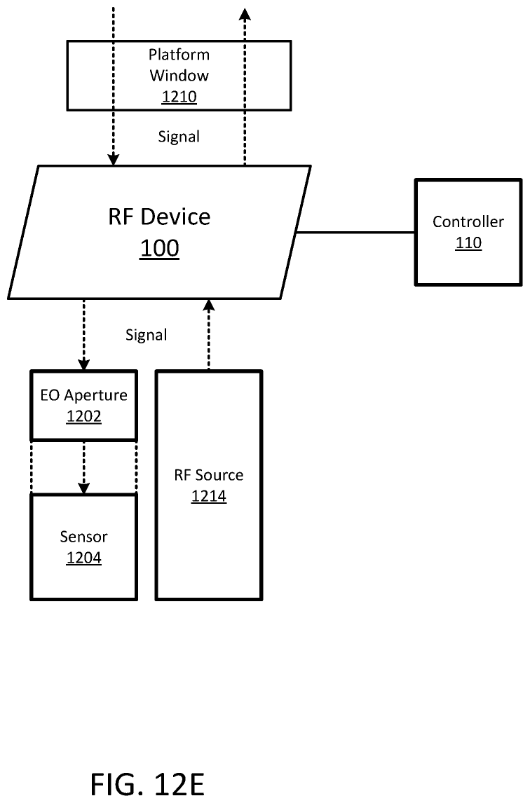

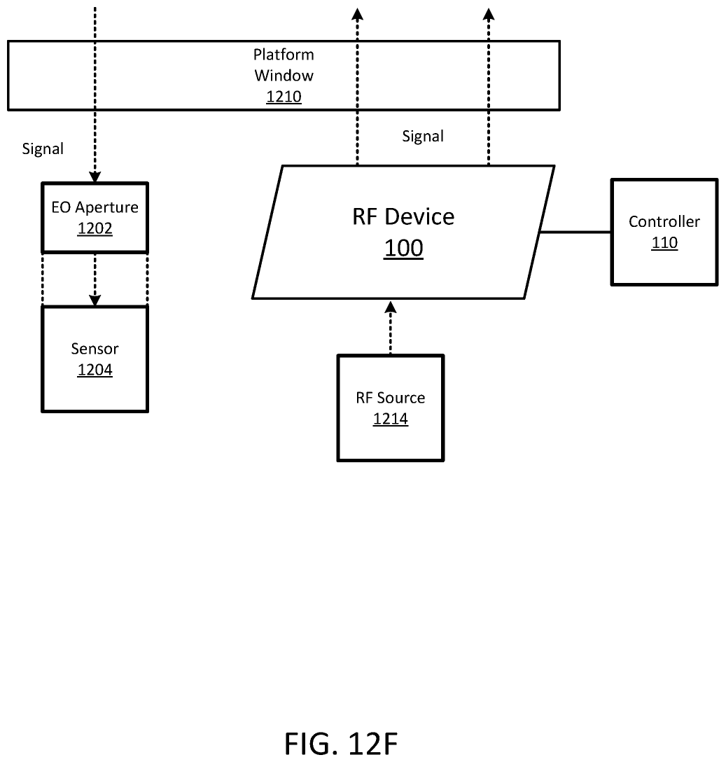

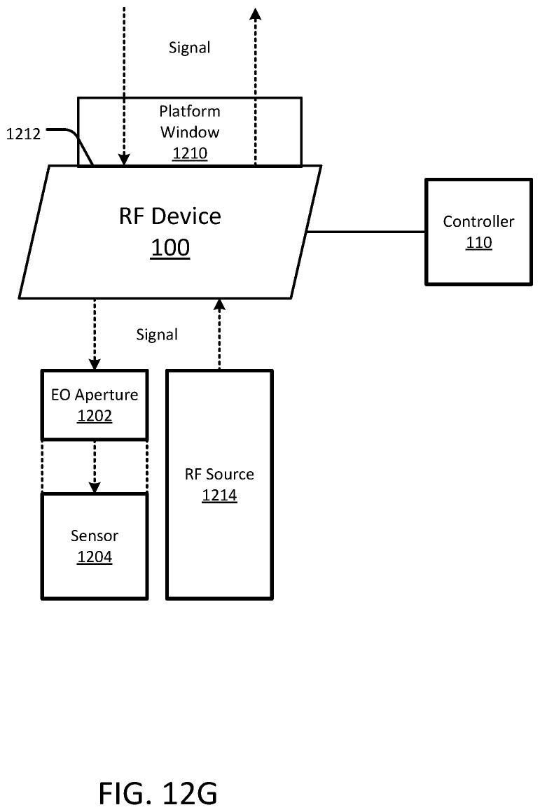

FIG. 12A is a schematic diagram of the optically transparent RF device 100 of FIGS. 1, 2, 3, 4A and 4B configured with an electro-optical (EO) aperture 1202, in accordance with another example of the present disclosure. In this example, the RF device 100 is positioned above an EO aperture 1202 such that a signal from a target 1206, or a portion of the signal, received by a sensor 1204 via the EO aperture 1202 passes through the RF device 100 or is entirely blocked by the RF device 100. The signal can include, for example, light (visible and/or infrared). The sensor 1204 can include, for example, an ambient light sensor, an infrared light sensor, an imaging sensor (e.g., a CMOS or CCD sensor), or other type of sensor configured to detect a signal or other radiation. In some examples, the RF device 100 is configured as an antenna array.

The EO aperture 1202, in some examples, is an electrically-controllable device (e.g., an electrochromatic medium that can be energized to attenuate or block energy) that, in combination with a lens, further focuses and/or steers the signal, and/or limits the amount of the signal that is received by the sensor 1204 after passing through the RF device 100. For example, the EO aperture 1202 can be controlled (e.g., by the controller 110 or by an independent controller) to limit the amount of light to pass through the aperture to the sensor 1204.

The controller 110 applies a voltage to a subset of the transistors 302 between a subset of the cells 104 to provide a reconfigurable electro-optical transmission layer, where at least a portion of the signal passing through the RF device 100 is a function of the signal in each selected cell 104. In this manner, a portion of the signal can radiate through the selected cells 104 or, alternatively, be blocked by the selected cells 104, such as to mask at least a portion of the signal from the EO aperture 1202. In some examples, the RF device 100 is transmissive at all wavelengths when fully deenergized and partially transmissive to certain wavelengths when partially or fully energized (e.g., one or more of the transistors 302 are switched on). The configuration of the RF device 100 can be changed by changing the selection of transistors 302 to activate different patterns of the cells 104. In this manner, the device 100 can be digitally tuned to limit or pass specific frequencies and/or limit/pass multiple electromagnetic wave polarizations.

FIG. 12B is a schematic diagram of the optically transparent RF device 100 of FIG. 12A, which in this example is positioned between the EO aperture 120 and a platform window 1210, such as glass or another optically transparent medium that encloses or otherwise protects the EO aperture 120 from external elements. The platform window can, for example, be mounted on an enclosure of an aircraft, a camera, a handheld device, a portable device, a fixed-location device, a ground vehicle, a space vehicle, or a maritime vessel. In this example, the RF device 100 is separate from the platform window 1210 and the signal, or a portion of the signal, received by the sensor 1204 via the EO aperture 1202 passes through the platform window 1210.

FIG. 12C is a schematic diagram of the optically transparent RF device 100 of FIG. 12A, which in this example is positioned adjacent to the EO aperture 120. In this example, the RF device 100 is separate from the platform window 1210 and a portion of the signal received by the sensor 1204 via the EO aperture 1202 passes through the platform window 1210. Another portion of the signal passes through the platform window 1210 and is processed by the RF device 100.

FIG. 12D is a schematic diagram of the optically transparent RF device 100 of FIG. 12A, which in this example is positioned on a surface 1212 of the platform window 1210. In this example, the RF device 100 is not separate from the platform window 1210 and the signal, or a portion of the signal, received by the sensor 1204 via the EO aperture 1202 passes through the platform window 1210 and the RF device 100.

In some examples, the RF device 100 is formed on the surface 1212 of the platform window 1210 (e.g., the platform window 1210 is the substrate 102) as a thin sheet. In some other examples, the substrate 102 of the RF device 100 is different from the platform window 1210, and the RF device 100 is adhered to the platform window 1210. Note that the platform window 1210 can be flat (planar) or curved (non-planar) and that the RF device 100 can conform to the shape of the surface 1212.

FIG. 12E is a schematic diagram of the optically transparent RF device 100 of FIG. 12A, which in this example is positioned between the EO aperture 120 and the platform window 1210. An RF source 1214 is positioned adjacent to the EO aperture 120. The RF source 1214 emits a signal that passes through the RF device 100 and the platform window 1210.

FIG. 12F is a schematic diagram of the optically transparent RF device 100 of FIG. 12A, which in this example is positioned adjacent to the EO aperture 120. In this example, the RF device 100 is separate from the platform window 1210 and the signal received by the sensor 1204 via the EO aperture 1202 passes through the platform window 1210. The RF source 1214 emits another signal that is processed by the RF device 100 and passes through the platform window 1210.

FIG. 12G is a schematic diagram of the optically transparent RF device 100 of FIG. 12A, which in this example is positioned on the surface 1212 of the platform window 1210. An RF source 1214 is positioned adjacent to the EO aperture 120. The RF source 1214 emits a signal that passes through the RF device 100 and the platform window 1210.

### Example Fabrication Methodology

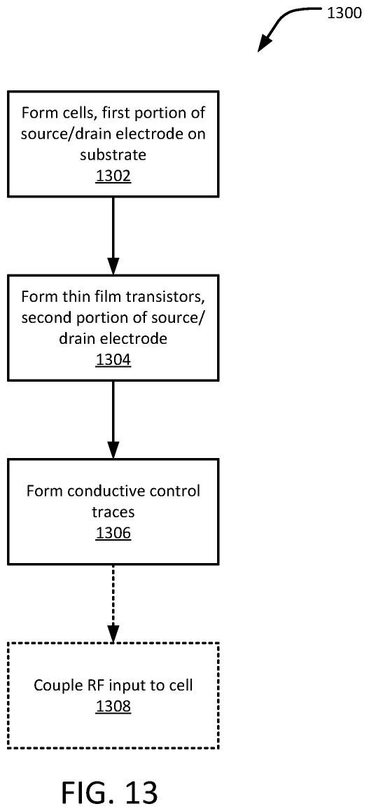

FIG. 13 is a flow diagram of a method 1300 of fabricating the RF device 100 of FIGS. 1-12, in accordance with an example of the present disclosure. The method 1300 includes forming 1302 a plurality of optically transparent conductive oxide thin film cells (e.g., the cells 104) on a substrate (e.g., the substrate 102) as an initial pattern on the substrate, such as shown in FIG. 2. The initial pattern of the substrate can include the cells as well as at least a portion of the corresponding source and drain electrodes (e.g., the electrodes 202). Each of the cells, including at least part of the source and drain electrodes, is separated by a gap (e.g., the gap 204).

The method 1300 further includes forming 1304 a plurality of thin film transistors (e.g., the transistors 302) in the gaps, such as shown in FIG. 3, with at least a portion of the source and drain electrodes providing the gaps and then being further built up along with the thin film transistors to provide the entire source and drain electrodes. Each of the transistors is electrically coupled to adjacent cells and is located in the gap between the respective cells. For instance, a transistor can be formed between any two adjacent cells such that each cell is electrically coupled to two, three, or four transistors, depending on the relative location of the cell to other cells, such as depicted in FIG. 3.

The method 1300 further includes forming a plurality of conductive control traces (e.g., the traces 402), where each trace is electrically coupled to one of the thin film transistors, such as shown in FIGS. 4A and 4B. The pitch (spacing) of the transistors and the cells can be set to provide sufficient spacing for fanout of the control traces used in a particular application. The traces fan out from each of the transistors to an edge of the substrate and are separated from each other with a dielectric layer where they overlap or otherwise cross each other to provide electrical isolation between the traces. Applying a voltage to one or more of the transistors via the traces causes a signal to be switched between an RF input and one or more of the cells. The cells can be configured to provide, for example, an antenna element, a filter, a frequency selective surface, or a passive radio frequency element.

In some examples, the method 1300 further includes comprising coupling the RF input (e.g., the RF input 108) to at least one of the cells. For example, the RF input can be coupled to a cell adjacent to an edge of the substrate, such as shown in FIG. 4A, or the RF input can be coupled to a cell closer to or at the center of the substrate, such as shown in FIG. 4B.

In some examples, each of the cells and electrodes includes one or more of: indium tin oxide, zinc oxide, indium zinc oxide, indium gallium zinc oxide, fluorine doped zinc oxide, and aluminum doped zinc oxide. In some examples, each of the transistors includes a source, a drain, and a gate, each being optically transparent, and wherein the source of a respective one of the transistors is electrically coupled to a first one of the cells, wherein the drain of the respective one of the transistors is electrically coupled to a second one of the cells, wherein the gate of the respective one of the transistors is electrically coupled to a contact on the substrate, and wherein the voltage is applied to the gate of the respective one of the transistors. In some examples, the cells are arranged in a grid pattern, such as shown in FIG. 2.

### Further Example Examples

The following examples pertain to further examples, from which numerous permutations and configurations will be apparent.

Example 1 provides a radio frequency device comprising an optically transparent, electrically insulating substrate; a plurality of optically transparent, electrically conductive cells disposed on the substrate, the cells configured to provide one or more of an antenna element, a filter, a frequency selective surface, and a passive radio frequency element; a thin film transistor coupled between an optically transparent electrode of a first one of the cells and an optically transparent electrode of a second one of the cells; and an optically transparent conductive control trace electrically coupled to a control terminal of the transistor.

Example 2 includes the subject matter of Example 1, further comprising a controller electrically coupled to the conductive control trace, the controller configured to output a voltage for switching the transistor to selectively couple the first one of the cells to the second one of the cells.

Example 3 includes the subject matter of any one of Examples 1 and 2, wherein at least one of the cells comprises an optically transparent conductive oxide thin film.

Example 4 includes the subject matter of Example 3, wherein the transparent conducting oxide film includes one or more of: indium tin oxide, zinc oxide, indium zinc oxide, indium gallium zinc oxide, fluorine doped zinc oxide, and aluminum doped zinc oxide.

Example 5 includes the subject matter of any one of Examples 1-4, wherein a width of at least one of the cells is approximately 1/16 of a wavelength λ of a signal applied to the at least one of the cells.

Example 6 includes the subject matter of any one of Examples 1-5, wherein the transistor includes an optically transparent source electrode, an optically transparent drain electrode, and an optically transparent gate electrode, wherein the source electrode of the transistor is electrically coupled to the electrode of the first one of the cells, wherein the drain electrode of the transistor is electrically coupled to the electrode of the second one of the cells, and wherein the gate electrode of the transistor is electrically coupled to the conductive control trace.

Example 7 includes the subject matter of Example 6, wherein the electrode of the first one of the cells is a first electrode, wherein the first one of the cells further includes a second optically transparent electrode, and wherein the device further comprises a dielectric between the gate electrode and the second electrode.

Example 8 includes the subject matter of any one of Examples 1-7, wherein the cells are arranged in a grid pattern, and wherein the transistor is located in a gap between the electrode of the first one of the cells and the electrode of the second one of the cells.

Example 9 includes the subject matter of any one of Examples 1-8, wherein the electrode of the first one of the cells is a first electrode, wherein the first one of the cells further includes a second electrode, and wherein the device further comprises a radio frequency (RF) input electrically coupled to the second electrode.

Example 10 provides a radio frequency (RF) device comprising a substrate; a plurality of optically transparent conductive oxide thin film cells disposed on the substrate, the cells configured to provide one or more of an antenna element, a filter, a frequency selective surface, and a passive radio frequency element; and a plurality of thin film transistors each electrically coupled to adjacent ones of the cells.

Example 11 includes the subject matter of Example 10, wherein each of the transparent conducting oxide film cells includes one or more of: indium tin oxide, zinc oxide, indium zinc oxide, indium gallium zinc oxide, fluorine doped zinc oxide, and aluminum doped zinc oxide.

Example 12 includes the subject matter of any one of Examples 10 and 11, wherein a width of each of the cells is approximately 1/16 of a wavelength λ of a signal applied to the device.

Example 13 includes the subject matter of any one of Examples 10-12, wherein each of the transistors includes a source electrode, a drain electrode, and a gate electrode, wherein the source electrode of a respective one of the transistors is electrically coupled to a first one of the cells, wherein the drain electrode of the respective one of the transistors is electrically coupled to a second one of the cells, and wherein the gate electrode of the respective one of the transistors is electrically coupled to a control signal contact on the substrate such that the respective one of the transistors is individually controllable to electrically couple the first one of the cells to the second one of the cells.

Example 14 includes the subject matter of Example 13, further comprising a transmit array, wherein the cells are arranged in a grid pattern and wherein the device is positioned above a feed antenna such that the signal emitted from the feed antenna passes through the transmit-array.

Example 15 includes the subject matter of Example 13, wherein the device is positioned above an EO aperture and configured to provide a reconfigurable electro-optical transmission layer, where at least a portion of a signal passing through the device is a function of the signal in one or more of the cells such that the signal, or a portion of the signal, received by a sensor via the EO aperture passes through the device or is entirely blocked by the device.

Example 16 provides a method of fabricating a radio frequency (RF) device, the method comprising forming a plurality of optically transparent conductive oxide thin film cells on a substrate; forming a first portion of a source electrode and a first portion of a drain electrode adjacent to each of the cells, the first portion of the source electrode being separated from the first portion of the drain electrode by a gap; forming a plurality of thin film transistors over the gap between adjacent ones of the cells; forming a second portion of the source electrode and a second portion of the drain electrode such that each of the thin film transistors is electrically coupled to adjacent ones of the cells via the source electrode and the drain electrode; and forming a plurality of conductive control traces each electrically coupled to one of the thin film transistors; wherein the thin film transistors are configured such that applying a voltage to one or more of the thin film transistors via one or more of the conductive control traces causes a signal to be switched between an RF input and one or more of the cells, the cells configured to provide one or more of an antenna element, a filter, a frequency selective surface, and a passive radio frequency element.

Example 17 includes the subject matter of Example 16, further comprising coupling the RF input to at least one of the cells.

Example 18 includes the subject matter of any one of Examples 16 and 17, wherein each of the transparent conducting oxide film cells includes one or more of: indium tin oxide, indium zinc oxide, indium gallium zinc oxide, fluorine doped zinc oxide, and aluminum doped zinc oxide.

Example 19 includes the subject matter of any one of Examples 16-18, wherein each of the transistors includes a source, a drain, and a gate, wherein the source of a respective one of the transistors is electrically coupled to a first one of the cells, wherein the drain of the respective one of the transistors is electrically coupled to a second one of the cells, wherein the gate of the respective one of the transistors is electrically coupled to a contact on the substrate, and wherein the voltage is applied to the gate of the respective one of the transistors.

Example 20 includes the subject matter of any one of Examples 16-19, wherein the cells are arranged in a grid pattern.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A radio frequency device comprising:
an optically transparent, electrically insulating substrate;
a plurality of optically transparent, electrically conductive cells disposed on the substrate, the cells configured to provide one or more of an antenna element, a filter, a frequency selective surface, and a passive radio frequency element;
a thin film transistor coupled between an optically transparent electrode of a first one of the cells and an optically transparent electrode of a second one of the cells; and
an optically transparent conductive control trace electrically coupled to a control terminal of the transistor.

2. The device of claim 1, further comprising a controller electrically coupled to the conductive control trace, the controller configured to output a voltage for switching the transistor to selectively couple the first one of the cells to the second one of the cells.

3. The device of claim 1, wherein at least one of the cells comprises an optically transparent conductive oxide thin film.

4. The device of claim 3, wherein the transparent conducting oxide film includes one or more of: indium tin oxide, zinc oxide, indium zinc oxide, indium gallium zinc oxide, fluorine doped zinc oxide, and aluminum doped zinc oxide.

5. The device of claim 1, wherein a width of at least one of the cells is approximately 1/16 of a wavelength λ of a signal applied to the at least one of the cells.

6. The device of claim 1, wherein the transistor includes an optically transparent source electrode, an optically transparent drain electrode, and an optically transparent gate electrode, wherein the source electrode of the transistor is electrically coupled to the electrode of the first one of the cells, wherein the drain electrode of the transistor is electrically coupled to the electrode of the second one of the cells, and wherein the gate electrode of the transistor is electrically coupled to the conductive control trace.

7. The device of claim 6, wherein the electrode of the first one of the cells is a first electrode, wherein the first one of the cells further includes a second optically transparent electrode, and wherein the device further comprises a dielectric between the gate electrode and the second electrode.

8. The device of claim 1, wherein the cells are arranged in a grid pattern, and wherein the transistor is located in a gap between the electrode of the first one of the cells and the electrode of the second one of the cells.

9. The device of claim 1, wherein the electrode of the first one of the cells is a first electrode, wherein the first one of the cells further includes a second electrode, and wherein the device further comprises a radio frequency (RF) input electrically coupled to the second electrode.

10. A radio frequency (RF) device comprising:
a substrate;
a plurality of optically transparent conductive oxide thin film cells disposed on the substrate, the cells configured to provide one or more of an antenna element, a filter, a frequency selective surface, and a passive radio frequency element; and
a plurality of thin film transistors each electrically coupled to adjacent ones of the cells.

11. The device of claim 10, wherein each of the transparent conducting oxide film cells includes one or more of: indium tin oxide, zinc oxide, indium zinc oxide, indium gallium zinc oxide, fluorine doped zinc oxide, and aluminum doped zinc oxide.

12. The device of claim 10, wherein a width of each of the cells is approximately 1/16 of a wavelength λ of a signal applied to the device.

13. The device of claim 10, wherein each of the transistors includes a source electrode, a drain electrode, and a gate electrode, wherein the source electrode of a respective one of the transistors is electrically coupled to a first one of the cells, wherein the drain electrode of the respective one of the transistors is electrically coupled to a second one of the cells, and wherein the gate electrode of the respective one of the transistors is electrically coupled to a control signal contact on the substrate such that the respective one of the transistors is individually controllable to electrically couple the first one of the cells to the second one of the cells.

14. The device of claim 13 further comprising a transmit array, wherein the cells are arranged in a grid pattern and wherein the device is positioned above a feed antenna such that the signal emitted from the feed antenna passes through the transmit-array.

15. The device of claim 13, wherein the device is positioned above an electro-optical (EO) aperture and configured to provide a reconfigurable electro-optical transmission layer, where at least a portion of a signal passing through the device is a function of the signal in one or more of the cells such that the signal, or a portion of the signal, received by a sensor via the EO aperture passes through the device or is entirely blocked by the device.

16. A method of fabricating a radio frequency (RF) device, the method comprising:
forming a plurality of optically transparent conductive oxide thin film cells on a substrate;
forming a first portion of a source electrode and a first portion of a drain electrode adjacent to each of the cells, the first portion of the source electrode being separated from the first portion of the drain electrode by a gap;
forming a plurality of thin film transistors over the gap between adjacent ones of the cells;
forming a second portion of the source electrode and a second portion of the drain electrode such that each of the thin film transistors is electrically coupled to adjacent ones of the cells via the source electrode and the drain electrode; and
forming a plurality of conductive control traces each electrically coupled to one of the thin film transistors;
wherein the thin film transistors are configured such that applying a voltage to one or more of the thin film transistors via one or more of the conductive control traces causes a signal to be switched between an RF input and one or more of the cells, the cells configured to provide one or more of an antenna element, a filter, a frequency selective surface, and a passive radio frequency element.

17. The method of claim 16, further comprising coupling the RF input to at least one of the cells.

18. The method of claim 16, wherein each of the transparent conducting oxide film cells includes one or more of: indium tin oxide, indium zinc oxide, indium gallium zinc oxide, fluorine doped zinc oxide, and aluminum doped zinc oxide.

19. The method of claim 16, wherein each of the transistors includes a source, a drain, and a gate, wherein the source of a respective one of the transistors is electrically coupled to a first one of the cells, wherein the drain of the respective one of the transistors is electrically coupled to a second one of the cells, wherein the gate of the respective one of the transistors is electrically coupled to a contact on the substrate, and wherein the voltage is applied to the gate of the respective one of the transistors.

20. The method of claim 16, wherein the cells are arranged in a grid pattern.
